(19) United States
(12) Patent Application Publication
(10) Pub. No.: US 2026/0040625 A1
(43) Pub. Date: Feb. 5, 2026

(54) INTEGRATED CIRCUIT, TRANSISTOR AND MANUFACTURING METHOD THEREOF

(71) Applicants: Taiwan Semiconductor Manufacturing Company, Ltd., Hsinchu (TW); Katholieke Universiteit Leuven, Leuven (BE)

(72) Inventors: Gerben DOORNBOS, Kessel-Lo (BE); Marcus Johannes Henricus Van Dal, Linden (BE); Jean-Pierre Locquet, Heverlee (BE)

(73) Assignees: Taiwan Semiconductor Manufacturing Company, Ltd., Hsinchu (TW); Katholieke Universiteit Leuven, Leuven (BE)

(21) Appl. No.: 18/792,561

(22) Filed: Aug. 2, 2024

(51) Int. Cl. H01L 29/49; H01L 29/66; H01L 29/786

(52) U.S. Cl. CPC H10D 30/6739; H10D 30/6755; H10D 30/6757; H10D 99/00

(57) ABSTRACT

A transistor is provided. The transistor includes a gate layer, a gate dielectric layer, a channel layer, and source and drain terminals. The gate dielectric layer is located on the gate layer. The channel layer is located on the gate dielectric layer, wherein lattice structures in a crystal plane of a material of the gate layer, in a crystal plane of a material of the gate dielectric layer and in a crystal plane of a material of the channel layer are substantially the same, a lattice constant in the crystal plane of each of the materials of the gate layer, the gate dielectric layer and the channel layer ranges from about 2.7 Å to about 3.1 Å, and at least one of the materials of the gate layer, the gate dielectric layer and the channel layer includes delafossite oxides. The source and drain terminals are disposed on the channel layer.

### BACKGROUND

Developments in shrinking sizes of semiconductor devices and electronic components make the integration of more devices and components into a given volume possible and lead to high integration density of various semiconductor devices and/or electronic components.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 5 are schematic cross-sectional views of various stages in a manufacturing method of a semiconductor device in accordance with some embodiments of the disclosure.

FIG. 6 is a schematic cross-sectional view of an integrated circuit in accordance with some embodiments of the disclosure.

FIG. 7 is a schematic cross-sectional view of a semiconductor device in accordance with some alternative embodiments of the disclosure.

FIG. 8 is a schematic cross-sectional view of a semiconductor device in accordance with some alternative embodiments of the disclosure.

FIG. 9 is a schematic cross-sectional view of a semiconductor device in accordance with some alternative embodiments of the disclosure.

FIG. 10 is a schematic cross-sectional view of a semiconductor device in accordance with some alternative embodiments of the disclosure.

FIG. 11 is a schematic cross-sectional view of a semiconductor device in accordance with some alternative embodiments of the disclosure.

FIG. 12 is a schematic cross-sectional view of a semiconductor device in accordance with some alternative embodiments of the disclosure.

FIG. 13 is a schematic cross-sectional view of a semiconductor device in accordance with some alternative embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first,” “second,” and the like, may be used herein for ease of description to describe similar or different element(s) or feature(s) as illustrated in the figures, and may be used interchangeably depending on the order of the presence or the contexts of the description.

It should be appreciated that the following embodiment(s) of the present disclosure provide applicable concepts that can be embodied in a wide variety of specific contexts. The specific embodiment(s) discussed herein are merely illustrative and are related to an integration structure containing more than one type of semiconductor devices, and are not intended to limit the scope of the present disclosure. Embodiments of the present disclosure describe the exemplary manufacturing process of integration structures formed with one or more semiconductor devices such as transistors and the integration structures fabricated there-from. Certain embodiments of the present disclosure are related to the structures including semiconductor transistors and other semiconductor devices. The substrates and/or wafers may include one or more types of integrated circuits or electronic components therein. The semiconductor device(s) may be formed on a bulk semiconductor substrate or a semiconductor-on-insulator substrate, where the semiconductor material is silicon, silicon germanium, gallium arsenide, indium phosphide, gallium nitride, gallium oxide, or the like. Alternatively, the semiconductor devices may also be formed on bulk insulating substrates, such as crystalline sapphire, or magnesium oxide. The embodiments are intended to provide further explanations but are not used to limit the scope of the present disclosure.

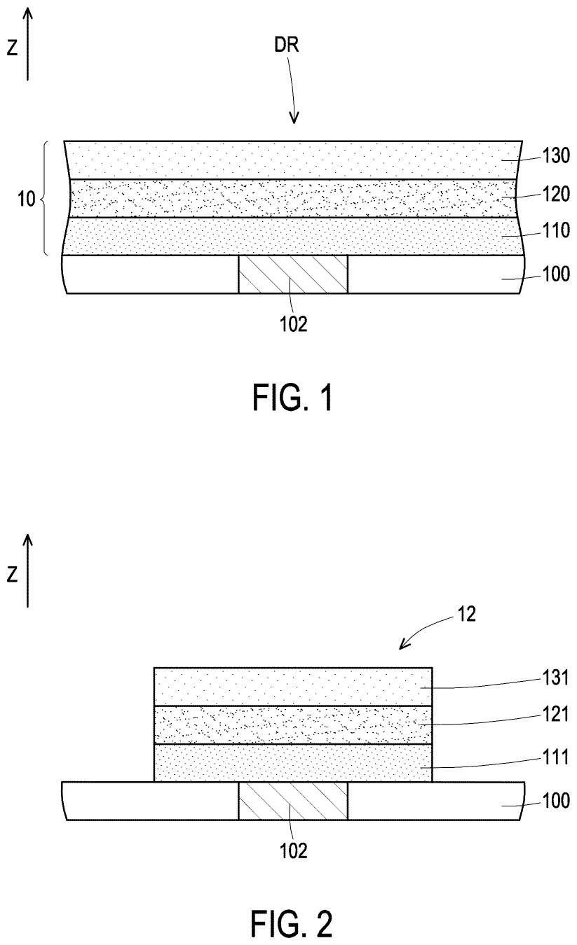

FIG. 1 through FIG. 5 are schematic cross-sectional views of various stages in a manufacturing method of a semiconductor device 50 in accordance with some embodiments of the disclosure. Although the steps of the method are illustrated and described as a series of acts or events, it will be appreciated that the illustrated ordering of such acts or events are not to be interpreted in a limiting sense. In addition, not all illustrated process or steps are required to implement one or more embodiments of the present disclosure.

From FIG. 1 through FIG. 5, schematic cross-sectional views of a device region DR of the semiconductor device 50 are shown. Referring to FIG. 1, in some embodiments, a dielectric layer 100 having one or more connection structures 102 therein is provided. As illustrated in FIG. 1, the connection structure 102 is formed such that the dielectric layer 100 laterally surrounds the connection structure 102. As shown in FIG. 1, in some embodiments, the connection structure 102 (only one is shown) is formed in the dielectric layer 100 within the device region DR. It is understood that the number of the connection structure 102 may be more than one, and the number or the configuration of the connection structure 102 should not be limited by the exemplary embodiments or drawings of this disclosure. In FIGS. 1-5, only a portion of the device region DR is shown for illustration purposes.

In some embodiments, the dielectric layer 100 is formed of low-k dielectric. For example, the dielectric layer 100 includes Phospho-Silicate Glass (PSG), Boro-Silicate Glass (BSG), Boron-Doped Phospho-Silicate Glass (BPSG), undoped Silicate Glass (USG), the like, or combinations thereof. In some embodiments, the dielectric layer 100 is formed of oxides or nitrides, such as silicon oxide, silicon nitride, or the like. In some embodiments, the material of the dielectric layer 100 includes polyimide, epoxy resin, acrylic resin, phenol resin, benzocyclobutene (BCB), polybenzooxazole (PBO), or any other suitable polymer-based dielectric material. The dielectric layer 100 may be formed on the substrate by suitable fabrication techniques such as spin-on coating, chemical vapor deposition (CVD), plasma-enhanced chemical vapor deposition (PECVD), or the like. In other embodiments, the dielectric layer 100 is a crystalline oxide, such as sapphire, or magnesium oxide. In these embodiments, the dielectric layer 100 may be part of a substrate, may be formed on a substrate by a suitable deposition technique, or may be transferred onto a substrate by layer transfer.

In some embodiments, the metallic material of the connection structure 102 includes copper, cobalt, ruthenium, tungsten, silver, aluminum, nickel, other suitable materials, alloys thereof, combinations thereof, and/or the like. In some embodiments, the connection structure 102 includes a metal compound such as titanium nitride, tantalum nitride, titanium aluminum, metal silicide, other suitable materials, combinations thereof, and/or the like.

In some embodiments, the connection structure 102 is formed by suitable fabrication techniques such as a damascene formation process. In some embodiments, the dielectric layer 100 is first patterned to form an opening therein through a photolithography and etching process. For example, the etching process includes an anisotropic etching process (e.g., dry etch) or an isotropic etching process (e.g., wet etch). In some embodiments, an etchant for the wet etch includes a combination of hydrogen fluoride (HF) and ammonia (NH₃), a combination of HF and tetramethylammonium hydroxide (TMAH), or the like. On the other hand, the dry etch process includes, for example, reactive ion etch (RIE), inductively coupled plasma (ICP) etch, electron cyclotron resonance (ECR) etch, neutral beam etch (NBE), and/or the like. Subsequently, a metallic material (not shown) is formed over the dielectric layer 100 and in the opening of the dielectric layer 100. The metallic material(s) may be deposited through chemical vapor deposition (CVD), physical vapor deposition (PVD), atomic layer deposition (ALD), or the like. Thereafter, a planarization process is performed on the metallic material until the dielectric layer 100 is exposed, so as to form the connection structure 102 that is embedded in the dielectric layer 100. For example, the planarization process includes a chemical mechanical polishing (CMP) process, a mechanical grinding process, an etching process, a combination thereof, or the like. In some embodiments, after the planarization process, the top surface of the connection structure 102 is substantially leveled (e.g., coplanar) with the top surface of the dielectric layer 100, within process variations.

In some embodiments, a barrier layer (not shown) may be optionally formed between the connection structure 102 and the dielectric layer 100, so as to avoid diffusion of atoms between elements. In some embodiments, the material of the barrier layer includes titanium nitride (TiN), tantalum nitride (TaN), titanium silicon nitride (TiSiN), tantalum silicon nitride (TaSiN), tungsten silicon nitride (WSiN), titanium carbide (TIC), tantalum carbide (TaC), titanium aluminum carbide (TiAlC), tantalum aluminum carbide (TaAlC), titanium aluminum nitride (TiAlN), tantalum aluminum nitride (TaAlN), or a combination thereof.

Still referring to FIG. 1, a gate material layer 110 is blanketly formed over the dielectric layer 100 and the connection structure 102. In one embodiment, the gate material layer 110 is in direct contact with the connection structure 102. In some embodiments, the gate material layer 110 includes one or more metallic material layers. In some embodiments, the gate material layer 110 is made of metallic oxides. In some embodiments, examples of metallic oxides include metallic delafossite oxides such as PtCoO₂, PdCoO₂, PdCrO₂, PdRhO₂, PdAlO₂. In such embodiments, the gate material layer 110 is formed as a layered crystal structure with a same crystal structure as the delafossite mineral CuFeO₂. In detail, in such embodiments, the gate material layer 110 has a 3R-rhombohedral, or a 2H-hexagonal type structure, and has in-plane electrical conductivity approaching that of elemental metals, such as Ag, Cu, and Au. In some embodiments, the in-plane lattice constant of the gate material layer 110 ranges from about 2.7 Å to about 3.1 Å. That is, the ab-plane (i.e., triangular plane) lattice constant of the gate material layer 110 ranges from about 2.7 Å to about 3.1 Å. In some alternative embodiments, examples of metallic oxides include V₂O₃, which crystallizes in a monoclinic phase, and also has a triangular lattice as surface (i.e., triangular plane). In some embodiments, the pseudo-triangle lattice constant of the gate material layer 110 ranges from about 2.7 Å to about 3.1 Å. In some embodiments, the gate material layer 110 is a crystalline metallic oxide layer. In some embodiments, the gate material layer 110 is a single crystalline metallic oxide layer or a polycrystalline metallic oxide layer. Preferably, in certain embodiments, the gate material layer 110 is a single crystalline metallic oxide layer. Further, in certain embodiments, the gate material layer 110 is formed in a fully crystalline state. In some embodiments, the gate material layer 110 is formed with a thickness ranging from about 10 nm to about 20 nm.

After the gate material layer 110 is formed, a gate dielectric material layer 120 is globally formed over the gate material layer 110. In some embodiments, the gate dielectric material layer 120 is made of insulating oxides having a triangular lattice as surface (i.e., triangular plane). As such, the crystal lattice of the dielectric material layer 120 can be matched with the crystal lattice of the gate material layer 110. In some embodiments, the pseudo-triangle lattice constant of the dielectric material layer 120 ranges from about 2.7 Å to about 3.1 Å. In some embodiments, examples of the said insulating oxides include SrTiO₃(111), MgO(111), or Me₂O₃, wherein Me is Al, Cr, and/or Ga. In some embodiments, examples of the said insulating oxides include Al₂O₃, Cr₂O₃, or Ga₂O₃. In some embodiments, examples of the said insulating oxides include ternary oxides, such as Al₂ₓCr₂₋₂ₓO₃, Al₂ₓGa₂₋₂ₓO₃, x varies between 0 and 1, for instance x is 0.5. In some embodiments, the dielectric material layer 120 is a crystalline insulating oxide layer. In some embodiments, the dielectric material layer 120 is a single crystalline insulating oxide layer or a polycrystalline insulating oxide layer. Preferably, in certain embodiments, the dielectric material layer 120 is a single crystalline insulating oxide layer. Further, in certain embodiments, the dielectric material layer 120 is formed in a fully crystalline state. In some embodiments, the dielectric material layer 120 is formed with a thickness ranging from about 5 nm to about 10 nm.

As shown in FIG. 1, after forming the gate dielectric material layer 120, a semiconductor material layer 130 is formed over the gate dielectric material layer 120 to form a stack structure 10. That is, the stack structure 10 includes the gate material layer 110, the gate dielectric material layer 120 and the semiconductor material layer 130 stacked in sequence from the bottom to the top along a direction Z. In some embodiments, the semiconductor material layer 130 is made of semiconducting oxides. In some embodiments, examples of semiconducting oxides include semiconducting delafossite oxides such as CuAlO₂, CuCrO₂, CuGaO₂, CuFeO₂, CuBO₂, AgAlO₂, AgCrO₂, AgGaO₂, AgFeO₂. In such embodiments, the semiconductor material layer 130 is formed as a layered crystal structure. In detail, in such embodiments, the semiconductor material layer 130 has p-type semiconductivity. In some embodiments, the semiconductor material layer 130 contains impurities to increase the carrier concentration. Examples of such impurities are Mg, Al, Ca, Ni, but other impurities may be used. The concentration of impurities is low enough such that the crystallinity of the layer is not changed. The concentration of impurities can be between 10¹⁵ and 10²⁰ atoms/cm³, e.g., 10¹⁸ atoms/cm³. In some embodiments, the in-plane lattice constant of the semiconductor material layer 130 ranges from about 2.7 Å to about 3.1 Å. That is, the ab-plane (i.e., triangular plane) lattice constant of the semiconductor material layer 130 ranges from about 2.7 Å to about 3.1 Å. It is noted that since the gate material layer 110 may be made of metallic delafossite oxides or V₂O₃, the gate dielectric material layer 120 is made of insulating oxides having a triangular lattice as surface, and the semiconductor material layer 130 is made of semiconducting delafossite oxides, the lattice structure in at least one crystal plane of the gate material layer 110, the lattice structure in at least one crystal plane of the gate dielectric material layer 120 and the lattice structure in at least one crystal plane of the semiconductor material layer 130 are substantially the same. In some embodiments, the at least one crystal plane is a triangular plane. Also, the crystal lattice of the semiconductor material layer 130 can be closely matched with the crystal lattice of the dielectric material layer 120 and the crystal lattice of the gate material layer 110, so that the layer stack 10 can be grown epitaxially, forming a pseudomorphic stack. In some embodiments, the semiconductor material layer 130 is formed with a thickness ranging from about 4 nm to about 8 nm.

In some embodiments, the semiconductor material layer 130 is a crystalline semiconducting oxide layer. In some embodiments, the semiconductor material layer 130 is a single crystalline semiconducting oxide layer or a polycrystalline semiconducting oxide layer. Preferably, in certain embodiments, the semiconductor material layer 130 is a single crystalline semiconducting oxide layer. Further, in certain embodiments, the semiconductor material layer 130 is formed in a fully crystalline state. Since the gate material layer 110, the dielectric material layer 120 and the semiconductor material layer 130 each may be formed in a fully crystalline state, the stack structure 10 is regarded as a fully crystalline stack structure. In this way, at the interfaces between the gate material layer 110 and the dielectric material layer 120, and between the dielectric material layer 120 and the semiconductor material layer 130, there may be no, or low, density of interface traps Dᵢₜ. In this context, having low Dᵢₜ means the interface traps do not impact the operation of layer stack 10 as part of a field-effect transistor. Low Dᵢₜ is below, for instance, 10¹¹ or 10¹² eV⁻¹ cm⁻². In some embodiments, in the stack structure 10, the lattice mismatch of the interface between the gate material layer 110 and the gate dielectric material layer 120, and the lattice mismatch of the interface between the gate dielectric material layer 120 and the semiconductor material layer 130 each is within about 10%. As such, through properly selecting of the materials of the gate material layer 110, the gate dielectric material layer 120 and the semiconductor material layer 130, minimal lattice mismatch is achieved and leading to low stress and low or no defectivity by stress relaxation in the stack structure 10. Further, through properly selecting of the materials of the gate material layer 110, the gate dielectric material layer 120 and the semiconductor material layer 130, minimal lattice mismatch is achieved in the stack structure 10, while the semiconductor material layer 130 may be strained appropriately to increase carrier mobility. Further, through properly selecting of the materials of the gate material layer 110, the gate dielectric material layer 120 and the semiconductor material layer 130, the gate material layer 110, the gate dielectric material layer 120 and the semiconductor material layer 130 are formed with high quality. Further, through properly selecting of the materials of the gate material layer 110, the gate dielectric material layer 120 and the semiconductor material layer 130, conduction band and valence band offsets can be selected such that electrons are confined to the gate material layer 110, holes are confined to the semiconductor material layer 130, and the gate dielectric material layer 120 electrically isolates the gate material layer 110 and the semiconductor material layer 130.

From another point of view, through properly selecting of the materials of the gate material layer 110, the gate dielectric material layer 120 and the semiconductor material layer 130, each of the gate material layer 110, the gate dielectric material layer 120 and the semiconductor material layer 130 is formed with their respective crystallographic c-axes oriented along the Z-direction, that is, the layer are c-axis oriented. As such, in the stack structure 10, at least one crystal plane of the gate material layer 110, at least one crystal plane of the gate dielectric material layer 120 and at least one crystal plane of the semiconductor material layer 130 are parallel with each other. Also, in the stack structure 10, at least one crystal plane of the gate material layer 110, at least one crystal plane of the gate dielectric material layer 120 and at least one crystal plane of the semiconductor material layer 130 are parallel to at least one surface of the gate material layer 110, at least one surface of the gate dielectric material layer 120 and at least one surface of the semiconductor material layer 130. In some embodiments, each of the at least one crystal plane of the gate material layer 110, the at least one crystal plane of the gate dielectric material layer 120 and the at least one crystal plane of the semiconductor material layer 130 is the triangular plane. In some embodiments, the at least one surface of the gate material layer 110 is the interface between the gate material layer 110 and the gate dielectric material layer 120, the at least one surface of the gate dielectric material layer 120 is the interface between the gate dielectric material layer 120 and the gate material layer 110 or the interface between the gate dielectric material layer 120 and the semiconductor material layer 130, and the at least one surface of the semiconductor material layer 130 is the interface between the semiconductor material layer 130 and the gate dielectric material layer 120. Further, due to crystallinity and c-axis orientation of the stack structure 10, the gate material layer 110 and the semiconductor material layer 130 are conduct electrical current primarily in-plane.

In some embodiments, the gate material layer 110, the gate dielectric material layer 120 and the semiconductor material layer 130 are formed through an epitaxial growth process. In some embodiments, the epitaxial growth technology comprises atomic layer deposition (ALD), physical vapor deposition (PVD), pulsed layer deposition (PLD), or molecular beam epitaxy (MBE). In some embodiments, the gate material layer 110, the gate dielectric material layer 120 and the semiconductor material layer 130 are formed sequentially and continuously in the same growth process and within the same reaction chamber. That is, the stack structure 10 (including the gate material layer 110, the gate dielectric material layer 120 and the semiconductor material layer 130) is formed by an in-situ growth process. Also, since the materials of the gate material layer 110, the gate dielectric material layer 120 and the semiconductor material layer 130 are properly selected (i.e., the materials having substantially the same lattice structure in the parallel crystal planes), through the same growth process, the gate material layer 110, the gate dielectric material layer 120 and the semiconductor material layer 130 can be formed within the same chamber in a self-aligned way. As such, a fully crystalline stack structure 10 with high quality layers therein can be easily controlled and formed by a single growth process, and thereby the manufacturing cost of the semiconductor device 50 is reduced and the manufacturing process of the semiconductor device 50 is simplified.

Optionally, after the growth process of the stack structure 10, an annealing process may be included to improve crystallinity, cure crystalline defects, or activate dopant atoms. Since the gate material layer 110, the gate dielectric material layer 120, and the semiconductor material layer 130 are properly selected, such that their crystalline structures match at their respective interfaces, and they may be formed sequentially in the same growth process, the optional annealing process may be performed at a low temperature. For instance, if the dielectric layer 100 is part of a back-end-of-line (BEOL) structure lying over a substrate, the temperature and time of the annealing process can be selected such that they are compatible with the BEOL materials. For instance, in some embodiments, the optional annealing process is performed at a temperature ranging from about 250° C. to about 400° C., for a duration from about 1 minute to about 60 minutes. In other embodiments, where the dielectric layer 100 does not overly a BEOL structure, the optional annealing process may be performed at a higher temperature, ranging from about 400° C. to about 650° C., although even higher temperatures may be possible.

In some embodiments, using the same growth process within the same reaction chamber, the gate material layer 110 is blanketly deposited over the dielectric layer 100 and the connection structure 102, the gate dielectric material layer 120 is blanketly deposited over the gate material layer 110, and then the semiconductor material layer 130 is blanketly formed over the gate dielectric material layer 120 by adjusting the stoichiometry during deposition. For deposition in an ALD chamber, the stoichiometry is controlled by tuning the flow rates of the different metal precursors. For deposition in a PVD or MBE chamber, the stoichiometry is controlled by selecting the metal or metal oxide target from which material is sputtered. For deposition in an MBE chamber, the stoichiometry is controlled by the flux of metal from different metal sources. That is, through the same growth process, the gate material layer 110, the gate dielectric material layer 120 and the semiconductor material layer 130 are formed sequentially and continuously with the same precursors, targets, or sources, applied over time in varying stoichiometric ratios. In certain embodiments, through properly selecting of the materials of the gate material layer 110, the gate dielectric material layer 120 and the semiconductor material layer 130, only three metal precursors, targets, or sources are required in the formation of the gate material layer 110, the gate dielectric material layer 120 and the semiconductor material layer 130.

In one embodiment, the gate material layer 110, the gate dielectric material layer 120 and the semiconductor material layer 130 are formed sequentially and continuously in the same process within the same reaction chamber, and the gate material layer 110 is made of PdAlO₂, the gate dielectric material layer 120 is made of Al₂O₃ and the semiconductor material layer 130 is made of CuAlO₂ by adjusting the stoichiometry of Pd precursor, target, or source, Al precursor, target, or source, Cu precursor, target, or source, and/or the oxygen source. In detail, as example of such embodiment for ALD growth, Pd (hfac) 2 is used as Pd precursor, trimethylaluminum is used as Al precursor, Cu(hfac)₂ is used as Cu precursor, water or ozone is used as the oxygen source, the growth temperature is ranged from about 150° C. to about 350° C., and a post-deposition annealing process is performed at about 250° C. to about 400° C. for about 1 minute to about 60 minutes in an N₂ atmosphere, for example.

In another embodiment, the gate material layer 110, the gate dielectric material layer 120 and the semiconductor material layer 130 are formed sequentially and continuously in the same process within the same reaction chamber, and the gate material layer 110 is made of PdCrO₂, the gate dielectric material layer 120 is made of Cr₂O₃ and the semiconductor material layer 130 is made of CuCrO₂ by adjusting the stoichiometry of Cr precursor, target, or source, Al precursor, target, or source, Cu precursors, target, or source and the oxygen source. In detail, as example of such embodiment for ALD growth, dichlorodioxochromium is used as Cr precursor, trimethylaluminum is used as Al precursor, Cu(hfac)₂ is used as Cu precursor, water or ozone is used as the oxygen source, the growth temperature is ranged from about 150° C. to about 350° C., and a post-deposition annealing process is performed at about 250° C. to about 400° C. for about 1 minute to about 60 minutes in an N₂ atmosphere, for example.

In some embodiments, as shown in FIG. 1, the gate material layer 110 is in direct contact with the connection structure 102, the gate dielectric material layer 120 is in direct contact with the gate material layer 110, and the semiconductor material layer 130 in direct contact with the gate dielectric material layer 120. However, the disclosure is not limited thereto. In some alternative embodiments, there is a seed layer (not shown) over the dielectric layer 100 and the connection structure 102 for the growth of the stack structure 10 with good crystalline properties. In certain embodiment, the material of the seed layer includes V₂O₃.

Referring to FIG. 1 and FIG. 2, in some embodiments, a patterning process is performed to the stack structure 10 of the gate material layer 110, the gate dielectric material layer 120 and the semiconductor material layer 130, so that the stack structure 10 is patterned to form a stack structure 12 having a gate layer 111, a gate dielectric layer 121 and a semiconductor layer 131 stacked in sequence from the bottom to the top along the direction Z. In some embodiments, the stack structure 10 of the gate material layer 110, the gate dielectric material layer 120 and the semiconductor material layer 130 is patterned into the stack structure 12 in one continuous patterning process. In some embodiments, the gate material layer 110, the gate dielectric material layer 120 and the semiconductor material layer 130 are sequentially patterned through multiple patterning processes. As shown in FIG. 2, in exemplary embodiments, the patterned stack structure 12 is disposed on the connection structure 102 and the dielectric layer 100, and exposes a portion of the dielectric layer 100. The sidewalls of the stack structure 12 in FIG. 2 may be shown to be vertically aligned or coplanar, and the stack structure 12 may be shown to be patterned into substantially the same pattern design or configuration. However, it is understood that the various layers of the stack structure 12 may have different patterns or configurations depending on product designs. In some embodiments, the patterning and the formation of the stack structure 12 include performing a photolithographic process and an etching process. In some embodiments, a photoresist pattern (not shown) may be used as an etching mask so that portions of the stack structure 10 uncovered by the photoresist pattern are removed during the etching process, and then the photoresist pattern is removed through a stripping process. In some embodiments, the etching process includes an isotropic etching process and/or an anisotropic etching process. For example, the stack structure 10 of the gate material layer 110, the gate dielectric material layer 120 and the semiconductor material layer 130 is partially removed through a wet etching process, a dry etching process, or a combination thereof.

The stack structure 12 is originated from the stack structure 10, so that the stack structure 12 is a fully crystalline stack structure with no or low interface trap density Dᵢₜ, with minimal lattice mismatch, with high crystalline quality, and with c-axis-orientation. Further, since the stack structure 12 is originated from the stack structure 10, minimal lattice mismatch is achieved in the stack structure 12, while the semiconductor layer 131 may be strained to increase carrier mobility.

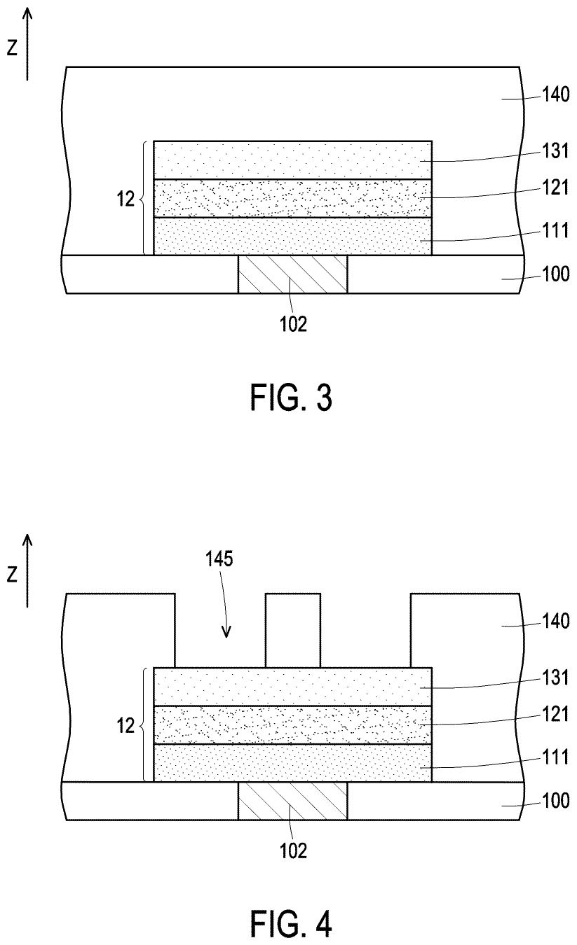

Referring to FIG. 3, an interlayer dielectric (ILD) layer 140 is formed blanketly over the dielectric layer 100 and fully covering the stack structure 12. In some embodiments, the material of the ILD layer 140 includes silicon oxide, silicon nitride, silicon oxynitride, or one or more low-k dielectric materials. Examples of low-k dielectric materials include silicate glass such as fluoro-silicate-glass (FSG), phospho-silicate-glass (PSG) and boro-phospho-silicate-glass (BPSG), BLACK DIAMOND®, SILK®, FLARE®, hydrogen silsesquioxane (HSQ), fluorinated silicon oxide (SiOF), amorphous fluorinated carbon, parylene, BCB (bis-benzocyclobutenes), or a combination thereof. It is understood that the ILD layer 140 may include one or more dielectric materials or one or more dielectric layers. In some embodiments, the ILD layer 140 is formed to a suitable thickness through chemical vapor deposition (CVD) (such as flowable CVD (FCVD), plasma enhanced CVD (PECVD), high Density Plasma CVD (HDPCVD), sub-atmospheric CVD (SACVD) and low-pressure CVD (LPCVD)), spin-on coating, or other suitable methods. For example, an interlayer dielectric material may be formed by PECVD to cover the exposed dielectric layer 100 and the stack structure 12 having the gate layer 111, the gate dielectric layer 121 and the semiconductor layer 131. Optionally, an etching or polishing process may be performed to reduce the thickness of the interlayer dielectric material until a desirable thickness to form the ILD layer 140.

Referring to FIG. 4, contact openings 145 are formed in the ILD layer 140 exposing the semiconductor layer 131. In some embodiments, the formation of the contact openings 145 includes forming a patterned mask layer (not shown) over the ILD layer 140, anisotropic etching the ILD layer 140 using the patterned mask layer as a mask to form the contact openings 145 exposing the semiconductor layer 131. As seen in FIG. 4, the contact openings 145 are shown with substantially vertical sidewalls. It is understood that the contact openings may be formed with slant sidewalls if feasible.

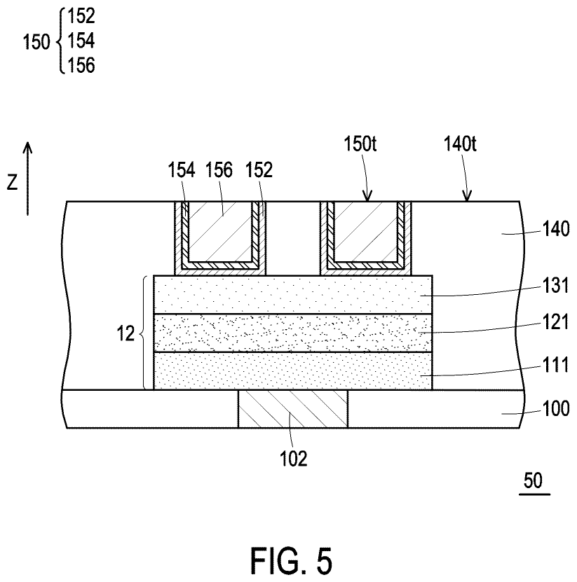

Thereafter, referring to FIG. 5, contact terminals 150 are formed in the contact openings 145, so as to form a transistor T of the semiconductor device 50. In some embodiments, as shown in FIG. 5, a barrier layer 152 is deposited over the contact openings 145 and conformally covers the sidewalls and bottoms of the contact openings 145. In some embodiments, a seed layer 154 is formed over the contact openings 145 and on the barrier layer 152. In some embodiments, the barrier layer 152 is formed before forming the seed layer 154 to prevent out-diffusion of the material of the seed layer 154. After the seed layer 154 is formed, metallic contacts 156 are then formed on the seed layer 154 within the contact openings 145 and fill the contact openings 145. However, the disclosure is not limited thereto. In some alternative embodiments, the contact terminal 150 may only include the metallic contact 156, or may only include the barrier layer 152 and the metallic contact 156 thereon.

In some embodiments, a barrier material (not shown) and a seed material (not shown) are sequentially formed over the contact openings 145 and conformally covering the exposed sidewalls and bottoms of the contact openings 145, and a metallic material (not shown) is then filled into the contact openings 145 to form the metallic contacts 156. The barrier material, the seed material and the metallic material may individually include one or more materials selected from tungsten, copper, ruthenium, molybdenum, tantalum, titanium, aluminum, alloys thereof, and nitrides thereof, for example. In some embodiments, the barrier material, the seed material and the metallic material may individually include 3D metal materials. In some embodiments, the barrier material is formed by ALD, CVD or PVD. In some embodiments, the seed material is formed by ALD, CVD or PVD. In some embodiments, the metallic material is formed by ALD, CVD or PVD. In alternative embodiments, the formation of the metallic material may include performing a plating process (such as electrochemical plating (ECP)). In some embodiments, the barrier material includes titanium nitride (TiN) formed by the metal organic CVD (MOCVD) process, the seed material includes tungsten formed by CVD, and the metallic material includes tungsten formed by the CVD process (especially tungsten CVD process). For example, the metallic contact 156 includes a tungsten contact and the barrier layer 152 includes a titanium nitride barrier layer.

In some embodiments, the extra barrier material, the extra seed material and the extra metallic material may be removed by performing a planarization process, an etching process, or other suitable processes. In some embodiments, the planarization process may include performing a chemical mechanical polishing (CMP) process. In some embodiments, the barrier layer 152, the seed layer 154 and the metallic contact 156 constitute contact terminals 150. As seen in FIG. 5, the top surface 140t of the ILD layer 140 is substantially flush with and levelled with the top surfaces 150t of the contact terminals 150.

In some embodiments, as shown in FIG. 5, the transistor T includes the stack structure 12 having the gate layer 111, the gate dielectric layer 121 and the semiconductor layer 131 sequentially stacked from the bottom to the top, and the contact terminals 150 located on the stack structure 12. In some embodiments, the semiconductor layer 131 functions as a channel layer of the transistor T, and the contact terminals 150 function as the source and drain terminals of the transistor T. As such, the transistor T includes a high-quality crystalline p-type oxide semiconductor channel, as mentioned above. In some embodiments, the transistor T is a p-type thin film transistor. In some embodiments, the transistor T is a bottom-gated transistor or a back-gate transistor.

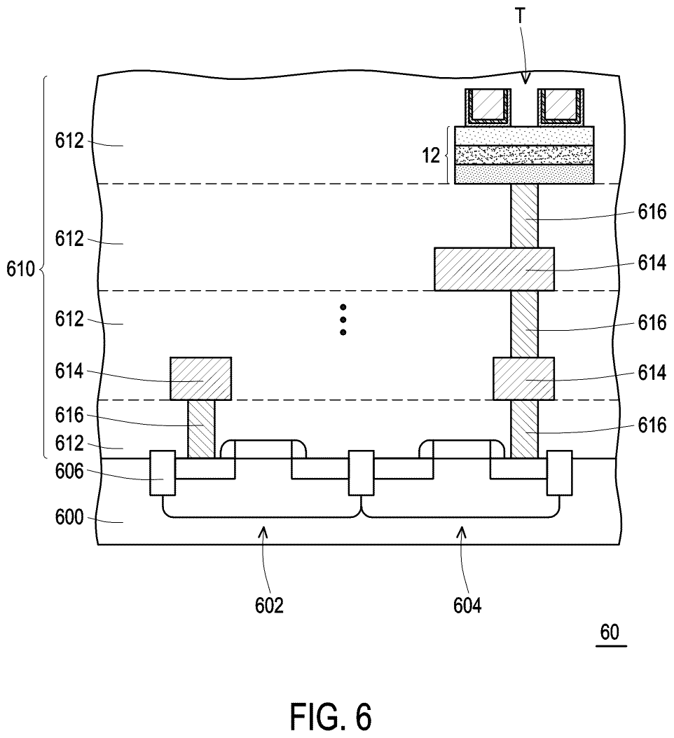

The semiconductor device 50 may be a portion of an integrated circuit. In some embodiments, the semiconductor device 50 comprises active devices such as oxide semiconductor thin film transistors, high voltage transistors, and/or other suitable components. In some embodiments, the semiconductor device 50 additionally includes passive components, such as resistors, capacitors, inductors, and/or fuses. In some embodiments, additional steps may be provided before, during, and after the process steps depicted from FIG. 1 to FIG. 5, and some of the steps described above may be replaced or eliminated, for additional embodiments of the method. In the illustrated embodiments, the described methods and structures may be formed compatible with the current semiconductor manufacturing processes. In exemplary embodiments, the described methods and structures are formed during BEOL processes. In such embodiments, the transistor T may be a BEOL-compatible thin-film transistor. It is noted that through properly selecting of the materials of the gate material layer 110, the gate dielectric material layer 120 and the semiconductor material layer 130, the required material crystallinity quality of the semiconductor layer 131 (i.e., the channel layer) may be achieved by deposition within the thermal budget constraints given by a BEOL process. Hereinafter, an embodiment of an integrated circuit including the transistor T will be described in conjunction with FIG. 6.

FIG. 6 is a schematic cross-sectional view of an integrated circuit 60 in accordance with some embodiments of the disclosure. In some embodiments, the integrated circuit 60 includes a substrate 600 and an interconnection structure 610. In some embodiments, the substrate 600 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The substrate 600 may be a bulk silicon substrate, a silicon-on-insulator (SOI) substrate, or a germanium-on-insulator (GOI) substrate.

In some embodiments, the substrate 600 includes one or more doped regions depending on circuit requirements (e.g., p-type semiconductor region or n-type semiconductor region). In some embodiments, the doped regions may be doped with p-type or n-type dopants. For example, the doped regions may be doped with p-type dopants, such as boron, or n-type dopants, such as phosphorus or arsenic; and/or combinations thereof. In some embodiments, the doped regions may be configured for an n-type metal-oxide-semiconductor (MOS) transistor or a p-type MOS (PMOS) transistor. In detail, as shown in FIG. 6, a NMOS 602 and a PMOS 604 are formed in and on the substrate 600, and the doped regions serve as source/drain regions of the NMOS 602 and the PMOS 604. In one embodiment, the NMOS 602 and/or the PMOS 604 are formed following the complementary MOS (CMOS) processes. In some embodiments, each of the NMOS 602 and the PMOS 604 further includes a metal gate and a channel under the metal gate. The channel is located between the source/drain regions to serve as a path for electron to travel when the NMOS 602 is on, or for holes when the PMOS 604 is turned on. In some embodiments, the NMOS 602 and the PMOS 604 are formed using a suitable front-end-of-line (FEOL) process. As shown in FIG. 6, the NMOS 602 and the PMOS 604 are partially embedded in the substrate 600. However, it should be understood that depending on the circuit requirement, the NMOS 602 and the PMOS 604 may be completely embedded in the substrate 600. As shown in FIG. 6, two transistors (i.e., the NMOS 602 and the PMOS 604) are formed in the substrate 600. However, it should be understood that one transistor or more than two transistors may be formed in the substrate 600 depending on the application of the integrated circuit 60.

As shown in FIG. 6, in some embodiments, more than one isolation structures 606 are formed in the substrate 600. In certain embodiments, the isolation structures 606 are shallow trench isolation (STI) structures. In other embodiments, the isolation structures 606 include local oxidation of silicon (LOCOS) structures. In some embodiments, the insulator material of the isolation structures 606 includes silicon oxide, silicon nitride, silicon oxynitride, a spin-on dielectric material, or a low-k dielectric material. In one embodiment, the insulator material may be formed by CVD such as high-density-plasma chemical vapor deposition (HDP-CVD) and sub-atmospheric CVD (SACVD) or formed by spin-on. In certain embodiments, the isolation structures 606 are also formed during the FEOL process.

As illustrated in FIG. 6, the interconnection structure 610 is disposed on the substrate 600. In some embodiments, the interconnection structure 610 includes a plurality of conductive vias 616, a plurality of conductive patterns 614, a plurality of dielectric layers 612 and the transistor T. In some embodiments, the interconnection structure 610 is formed using a suitable back-end of line (BEOL) process. As such, the transistor T embedded in the interconnection structure 610 is referred to as a BEOL device. As illustrated in FIG. 6, the conductive patterns 614 and the transistor T are embedded in the dielectric layers 612. On the other hand, the conductive vias 616 penetrate through the dielectric layers 612. In some embodiments, the conductive patterns 614 located at different level heights are connected to one another through the conductive vias 616. In other words, the conductive patterns 614 are electrically connected to one another through the conductive vias 616.

In some embodiments, the bottommost conductive vias 616 are connected to the NMOS 602 and the PMOS 604. In other words, the bottommost conductive vias 616 establish electrical connection between the NMOS 602, the PMOS 604 and the conductive patterns 614. As illustrated in FIG. 6, the bottommost conductive vias 616 are connected to source/drain regions of the NMOS 602 and the PMOS 604. It should be noted that in some alternative cross-sectional views, the bottommost conductive vias 616 are also connected to the metal gates of the NMOS 602 and the PMOS 604. That is, in some embodiments, the bottommost conductive vias 616 may be referred to as “contact structures” of the NMOS 602 and the PMOS 604. Further, as illustrated in FIG. 6, one of the conductive vias 616 is connected to the gate layer 111 of the transistor T. In other words, the said conductive via 616 establishes electrical connection between the transistor T and the conductive pattern 614. It is noted that, referring back to FIG. 1, the connection structure 102 embedded in the dielectric layer 100 may be a conductive via of an interconnection structure for electrical connection and interconnection, and the conductive via (i.e., connection structure 102) as depicted in FIG. 1 is similar to the conductive via 616 as depicted in FIG. 6. Further, as shown in FIG. 6, the transistor Tis electrically connected to the PMOS 604.

In some embodiments, the material of the dielectric layers 612 includes silicon oxide, a spin-on dielectric material, a low-k dielectric material or a combination thereof. The formation of the dielectric layers 612 includes performing one or more processes by CVD or by spin-on, for example. In some embodiments, the materials of the conductive patterns 614 and the conductive vias 616 include aluminum (Al), aluminum alloys, copper (Cu), copper alloys, tungsten (W), or combinations thereof. It should be noted that the number of the dielectric layers 612, the number of the conductive patterns 614, and the number of the conductive vias 616 illustrated in FIG. 6 are merely for illustrative purposes, and the disclosure is not limited thereto. In some alternative embodiments, fewer or more layers of the dielectric layers 612, the conductive patterns 614, and/or the conductive vias 616 may be formed depending on the circuit design. For simplicity, one transistor T is shown in FIG. 6. However, it should be understood that more than one transistor T may be embedded in the dielectric layers 612 depending on the application of the integrated circuit 60.

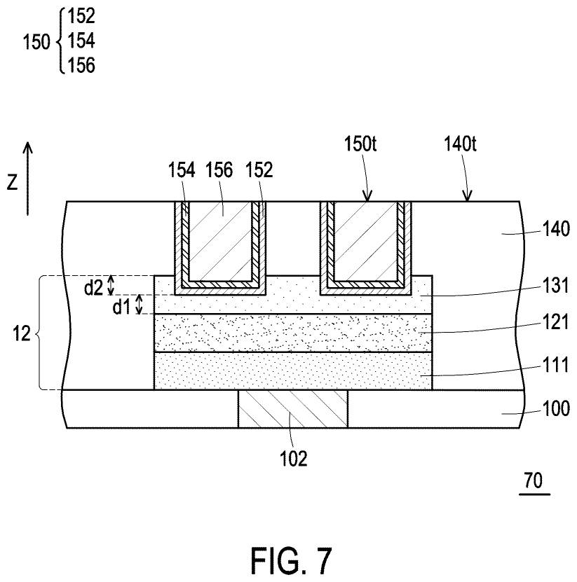

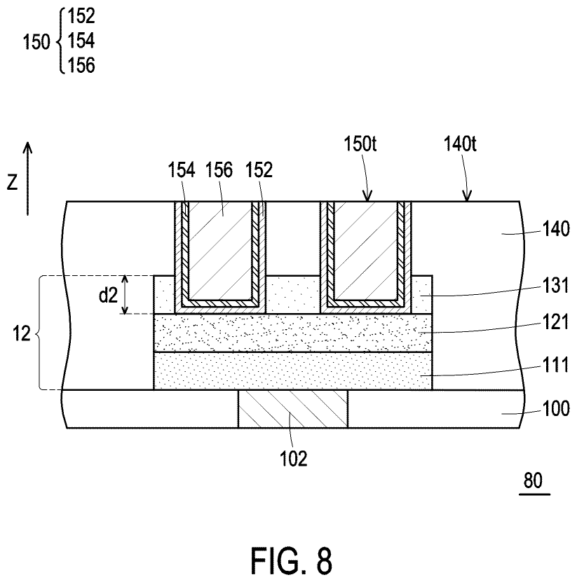

It is understood by those skilled in the art that in the delafossite atomic structure, there are two alternating planar layers (i.e., alternating layers form the layered crystal structure). As such, due to the structure, the electrical conductivity of delafossite oxides is strongly anisotropic and highest within the ab-plane. That is, the semiconductor layer 131 exhibits the inherent in-plane electrical conductivity. In this way, as shown in FIG. 5, by arranging the bottom surfaces of the contact terminals 150 directly being in contact with the top surface of the semiconductor layer 131, the high contact resistance Re results between the contact terminals 150 and the semiconductor layer 131. In order to reduce the contact resistance between the contact terminals 150 and the semiconductor layer 131, hereinafter, other embodiments will be described in conjunction with FIG. 7 and FIG. 8.

FIG. 7 is a schematic cross-sectional view of a semiconductor device 70 in accordance with some alternative embodiments of the disclosure. The semiconductor device 70 illustrated in FIG. 7 is similar to the semiconductor device 50 illustrated in FIG. 5, hence the same reference numerals are used to refer to the same or liked parts, and its detailed description will be omitted herein. The differences between the semiconductor device 70 and the semiconductor device 50 will be described below.

Referring to FIG. 7, in the semiconductor device 70, the contact terminals 150 extend into the semiconductor layer 131. In detail, as shown in FIG. 7, a portion of the contact terminal 150 is embedded in the semiconductor layer 131. Also, as shown in FIG. 7, a portion of the sidewall of the contact terminal 150 is directly in contact with the semiconductor layer 131. That is, the sidewall of the contact terminal 150 is partially in contact with the semiconductor layer 131. According to the descriptions with respect to FIG. 1 to FIG. 5, those skilled in the art should understand that in the formation process of the semiconductor device 70, a portion of the semiconductor layer 131 is also removed to form the contact openings 145. That is, during the formation process of the semiconductor device 70, the contact openings 145 are formed in the ILD layer 140 and extend into the semiconductor layer 131. As shown in FIG. 7, the bottom surface of the contact terminal 150 is separated from the gate dielectric layer 121 by a non-zero distance d1 in the direction Z. On the other hand, the contact terminal 150 extends to a non-zero depth d2 into the semiconductor layer 131 in the direction Z. It is noted that, optimal selection of distance d1 or depth d2 depends on resistivity, but may also be process-dependent. Further, it is noted that by arranging the sidewall of the contact terminal 150 partially contacting with the semiconductor layer 131, the carriers are easily transported from the contact terminal into the layered crystal structure (i.e., the ab-plane), or vice versa. As such, due to the inherent in-plane electrical conductivity of the semiconductor layer 131, the contact resistance between the contact terminals 150 and the semiconductor layer 131 can be reduced.

Since optimal selection of distance d1 or depth d2 depends on resistivity or is process-dependent, there may be no distance d1 between the contact terminals 150 and the gate dielectric layer 121. Hereinafter, this other embodiment will be described in conjunction with FIG. 8.

FIG. 8 is a schematic cross-sectional view of a semiconductor device 80 in accordance with some alternative embodiments of the disclosure. The semiconductor device 80 illustrated in FIG. 8 is similar to the semiconductor device 70 illustrated in FIG. 7, hence the same reference numerals are used to refer to the same or liked parts, and its detailed description will be omitted herein. The differences between the semiconductor device 80 and the semiconductor device 70 will be described below.

Referring to FIG. 8, in the semiconductor device 80, the contact terminals 150 extend into the semiconductor layer 131 and contact the gate dielectric layer 121. In some embodiments, as shown in FIG. 8, the contact terminals 150 are in direct contact with the top surface of the gate dielectric layer 121. That is, there is no non-zero distance d1 (shown in FIG. 7) between the contact terminals 150 and the gate dielectric layer 121, and the non-zero depth d2 is equal to the thickness of the semiconductor layer 131. On the other hand, the contact terminals 150 fully penetrate through the semiconductor layer 131. It is also noted that by arranging the sidewall of the contact terminal 150 partially contacting with the semiconductor layer 131, the carriers are easily transported from the contact terminal into the layered crystal structure (i.e., the ab-plane), or vice versa. As such, due to the inherent in-plane electrical conductivity of the semiconductor layer 131, the contact resistance between the contact terminals 150 and the semiconductor layer 131 can be reduced.

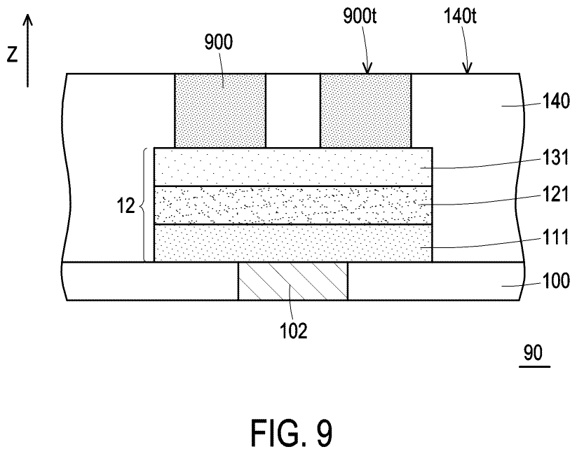

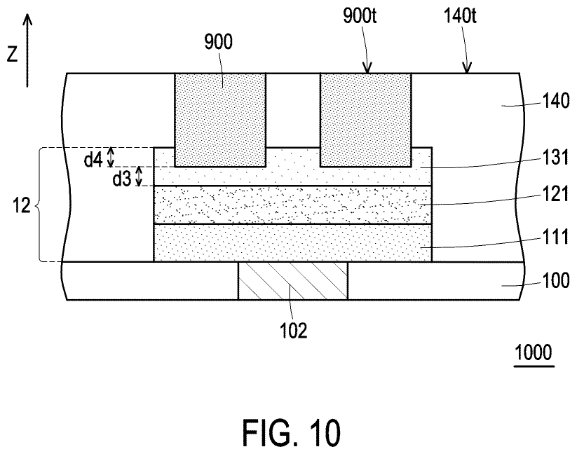

In the semiconductor device 50, the material of the contact terminal 150 includes 3D metal material. However, the disclosure is not limited thereto. In some alternative embodiments, the material of the contact terminal 150 may include metallic oxides. Hereinafter, other embodiments will be described with reference to FIG. 9 and FIG. 10.

FIG. 9 is a schematic cross-sectional view of a semiconductor device 70 in accordance with some alternative embodiments of the disclosure. The semiconductor device 90 illustrated in FIG. 9 is similar to the semiconductor device 50 illustrated in FIG. 5, hence the same reference numerals are used to refer to the same or liked parts, and its detailed description will be omitted herein. The differences between the semiconductor device 90 and the semiconductor device 50 will be described below.

Referring to FIG. 9, in the semiconductor device 90, the contact terminals 900 are made of metallic oxides. In some embodiments, examples of metallic oxides include metallic delafossite oxides such as PtCoO₂, PdCoO₂, PdCrO₂, PdRhO₂, PdAlO₂. In such embodiments, the contact terminals 900 are formed as a layered crystal structure with the same crystal structure as the delafossite mineral CuFeO₂. In detail, in such embodiments, the contact terminal 900 has a 3R-rhombohedral, or a 2H-hexagonal type structure, and has in-plane electrical conductivity approaching that of elemental metals, such as Ag, Cu, and Au. In some embodiments, the material of the contact terminals 900 is the same as the material of the gate layer 111. However, the disclosure is not limited thereto. In some alternative embodiments, the material of the contact terminals 900 is different from the material of the gate layer 111. It is noted that through properly selecting the materials of the semiconductor layer 131 and the contact terminal 900, band alignment between the contact terminal 900 (i.e., metallic oxides) and the valence band of the semiconductor layer 131 (i.e., semiconducting oxides) could provide ohmic contact, i.e., a Schottky barrier between contact terminal 900 and semiconductor layer 131 is low.

Since the contact terminals 900 are made of metallic oxides, the material layer used for forming the contact terminals 900 can be formed in-situ with the gate material layer 110, the gate dielectric material layer 120 and the semiconductor material layer 130. According to the descriptions with respect to FIG. 1 to FIG. 5, those skilled in the art should understand that in some embodiments, in the formation process of the semiconductor device 90, the gate material layer 110, the gate dielectric material layer 120, the semiconductor material layer 130 and the material layer for forming the contact terminals 900 are formed sequentially and continuously in the same growth process within the same reaction chamber to form a stack structure with four layers therein. Then, a patterning process is performed to the stack structure of the gate material layer 110, the gate dielectric material layer 120, the semiconductor material layer 130 and the material layer for forming the contact terminals 900, so that the said stack structure is patterned to form another stack structure having a gate layer 111, a gate dielectric layer 121, a semiconductor layer 131 and a patterned material layer for forming the contact terminals 900 stacked in sequence from the bottom to the top. Next, another patterning process is performed to the patterned material layer for forming the contact terminals 900 to form the contact terminals 900. The patterning process for forming the four-layered stack structure and the patterning process for forming the contact terminals 900 are similar to the patterning process for the stack structure 12 in FIG. 2, so other detailed description thereof is omitted herein.

In the formation process of the semiconductor device 90, after the contact terminals 900 are formed, the ILD layer 140 is formed over the dielectric layer 100, fully covering the stack structure 12 and laterally covering the contact terminals 900. In some embodiments, a planarization process, an etching process, or other suitable processes is performed to form the ILD layer 140. In some embodiments, the planarization process may include performing a CMP process. As seen in FIG. 9, the top surface 140t of the ILD layer 140 is substantially flush with and levelled with the top surfaces 900t of the contact terminals 900. It is noted that in the formation process of the semiconductor device 90, the contact terminals 900 can be formed without forming contact openings of the ILD layer 140 exposing the semiconductor layer 131. This process where the semiconductor layer 131 is not exposed to an etch process, protects the semiconductor layer 131 from the etch damage resulting from the formation of contact openings.

In some alternative embodiments, the formation process of the contact terminals 900 is similar with that of the contact terminals 150 illustrated in FIG. 4 to FIG. 5 except that the material of the contact terminals 900 is different from that of the contact terminals 150. In such embodiments, after the contact openings 145 (as shown in FIG. 4) are formed over the stack structure 12 (as shown in FIG. 4), the contact terminals 900 are formed through an epitaxial growth process within the contact openings 145. That is, the epitaxial growth process of the contact terminals 900 is performed after the stack structure 12 is formed. As such, the epitaxial growth process of the contact terminals 900 is referred to as an ex-situ epitaxial growth process. In some embodiments, the epitaxial growth technology comprises ALD, PVD (such as, PLD), or MBE.

As shown in FIG. 9, the bottom surface of the contact terminal 900 is in direct contact with the top surface of the semiconductor layer 131. However, the disclosure is not limited thereto. In some alternative embodiments, the contact terminal 900 may extend into the semiconductor layer 131. Hereinafter, other embodiment will be described with reference to FIG. 10.

FIG. 10 is a schematic cross-sectional view of a semiconductor device 70 in accordance with some alternative embodiments of the disclosure. The semiconductor device 1000 illustrated in FIG. 10 is similar to the semiconductor device 90 illustrated in FIG. 9, hence the same reference numerals are used to refer to the same or liked parts, and its detailed description will be omitted herein. The differences between the semiconductor device 1000 and the semiconductor device 90 will be described below.

Referring to FIG. 10, in the semiconductor device 1000, the contact terminals 900 extend into the semiconductor layer 131. In detail, as shown in FIG. 10, a portion of the contact terminal 900 is embedded in the semiconductor layer 131. Also, as shown in FIG. 10, a portion of the sidewall of the contact terminal 900 is directly in contact with the semiconductor layer 131. That is, the sidewall of the contact terminal 900 is partially in contact with the semiconductor layer 131. According to the descriptions with respect to FIG. 1 to FIG. 5 and FIG. 9, those skilled in the art should understand that in the formation process of the semiconductor device 1000, a portion of the semiconductor layer 131 is also removed to form the contact openings 145. That is, during the formation process of the semiconductor device 1000, the contact openings 145 are formed in the ILD layer 140 and extend into the semiconductor layer 131. From another point of view, the contact terminals 900 of the semiconductor device 1000 only can be formed ex-situ after the stack structure 12 is formed.

As shown in FIG. 10, the bottom surface of the contact terminal 900 is separated from the gate dielectric layer 121 by a non-zero distance d3 in the direction Z. On the other hand, the contact terminal 900 extends to a non-zero depth d4 into the semiconductor layer 131 in the direction Z. It is noted that, optimal distance d3 or depth d4 depends on resistivity, but may also be process-dependent. As such, in some alternative embodiments, there may be no distance d3 between the contact terminals 900 and the gate dielectric layer 121, with reference to the embodiment of FIG. 8. Further, it is noted that by arranging the sidewall of the contact terminal 900 partially contacting with the semiconductor layer 131, the carriers are easily transported through the layered crystal structure of the contact terminal 900 and the semiconductor layer 131. As such, due to the inherent in-plane electrical conductivity of the contact terminal 900 and the semiconductor layer 131, the contact resistance between the contact terminals 900 and the semiconductor layer 131 can be reduced.

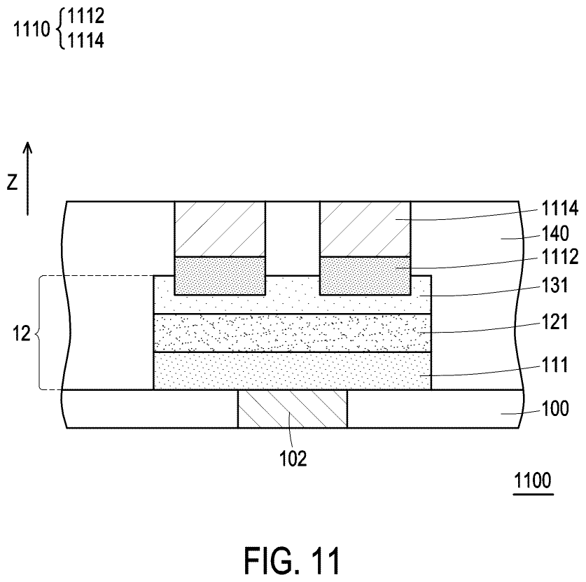

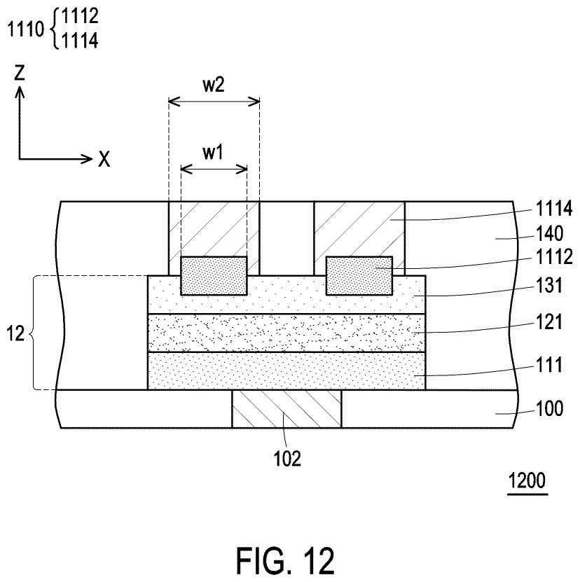

In each of the semiconductor devices 90, 1000, the contact terminal is made of a single material. However, the disclosure is not limited thereto. In some alternative embodiments, the contact terminal may be made of more than one material. Hereinafter, other embodiments will be described with reference to FIG. 11 and FIG. 12.

FIG. 11 is a schematic cross-sectional view of a semiconductor device 1100 in accordance with some alternative embodiments of the disclosure. The semiconductor device 1100 illustrated in FIG. 11 is similar to the semiconductor device 1000 illustrated in FIG. 10, hence the same reference numerals are used to refer to the same or liked parts, and its detailed description will be omitted herein. The differences between the semiconductor device 1100 and the semiconductor device 1100 and the semiconductor device 1000 will be described below.

Referring to FIG. 11, in the semiconductor device 1100, each of the contact terminals 1110 includes a first portion 1112 and a second portion 1114 located on the first portion 1112. That is, the contact terminal 1110 is formed as a composite stack. In some embodiments, the first portion 1112 is made of metallic oxides. In some embodiments, examples of metallic oxides include metallic delafossite oxides such as PtCoO₂, PdCoO₂, PdCrO₂, PdRhO₂, PdAlO₂. In such embodiments, the first portion 1112 is formed as a layered crystal structure with a same crystal structure as the delafossite mineral CuFeO₂. In detail, in such embodiments, the first portion 1112 has a 3R-rhombohedral, or a 2H-hexagonal type structure, and has in-plane electrical conductivity approaching that of elemental metals, such as Ag, Cu, and Au. In some embodiments, the material of the first portion 1112 is the same as the material of the gate layer 111. However, the disclosure is not limited thereto. In some alternative embodiments, the material of the first portion 1112 is different from the material of the gate layer 111. It is noted that through properly selecting of the materials of the semiconductor layer 131 and the first portion 1112, band alignment between the first portion 1112 (i.e., metallic oxides) and the valence band of the semiconductor layer 131 (i.e., semiconducting oxides) could provide ohmic contact. Further, as shown in FIG. 11, a portion of the first portion 1112 is embedded in the semiconductor layer 131. Also, as shown in FIG. 11, a portion of the sidewall of the first portion 1112 is directly in contact with the semiconductor layer 131. That is, the sidewall of the first portion 1112 is partially in contact with the semiconductor layer 131. As such, it is noted that by arranging the sidewall of the first portion 1112 partially contacting with the semiconductor layer 131, the carriers are easily transported through the ab-plane of the first portion 1112 and the semiconductor layer 131. As such, due to the inherent in-plane electrical conductivity of the first portion 1112 and the semiconductor layer 131, the contact resistance between the contact terminals 1110 and the semiconductor layer 131 can be reduced.

In some embodiments, the second portion 1114 is made of 3D metal material. In some embodiments, examples of 3D metal material include tungsten, copper, ruthenium, molybdenum, tantalum, titanium, aluminum, alloys thereof, and nitrides thereof. It is noted that compared to the contact terminal 900 only made of metallic oxides, the resistance of the contact terminal 1110 including a part of 3D metal material (i.e., including the second portion 1114) may be reduced. Further, according to the descriptions with respect to FIG. 5, those skilled in the art should understand that the second portion 1114 of the contact terminal 1110 may include the barrier layer, the seed layer over the barrier layer, and the metallic contact over the seed layer. However, the disclosure is not limited thereto. In some alternative embodiments, the second portion 1114 of the contact terminal 1110 may only include the barrier layer and the metallic contact thereon.

FIG. 12 is a schematic cross-sectional view of a semiconductor device 1200 in accordance with some alternative embodiments of the disclosure. The semiconductor device 1200 illustrated in FIG. 12 is similar to the semiconductor device 1100 illustrated in FIG. 11, hence the same reference numerals are used to refer to the same or liked parts, and its detailed description will be omitted herein. The differences between the semiconductor device 1200 and the semiconductor device 1100 will be described below.

Referring to FIG. 12, in the semiconductor device 1200, the dimension of the first portion 1112 is different from the dimension of the second portion 1114. In detail, as shown in FIG. 12, the dimension w1 of the first portion 1112 along a direction X perpendicular to the direction Z is smaller than the dimension w2 of the second portion 1114 along a direction X perpendicular to the direction Z. Further, a portion of the first portion 1112 is laterally surrounded by the second portion 1114. That is, the sidewall of the first portion 1112 is partially in contact with the second portion 1114. It is noted that by tuning the dimension relationship between the first portion 1112 and the second portion 1114 to laterally surrounding the first portion 1112 by the second portion 1114, the contact surface area between the first portion 1112 and the second portion 1114 is increased, and the carriers from the second portion 1114 are easily transported into or from the layered crystal structure of the first portion 1112. As such, the contact resistance between the first portion 1112 and the second portion 1114 can be reduced.

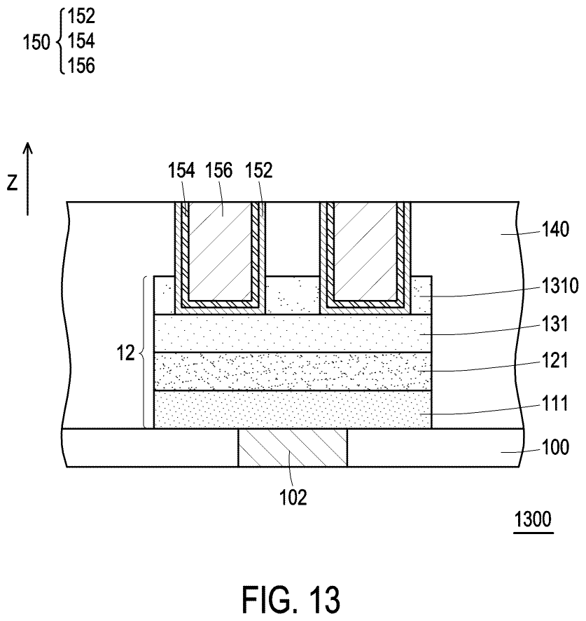

FIG. 13 is a schematic cross-sectional view of a semiconductor device 1200 in accordance with some alternative embodiments of the disclosure. The semiconductor device 1300 illustrated in FIG. 13 is similar to the semiconductor device 50 illustrated in FIG. 5, hence the same reference numerals are used to refer to the same or liked parts, and its detailed description will be omitted herein. The differences between the semiconductor device 1300 and the semiconductor device 50 will be described below.

Referring to FIG. 13, in the semiconductor device 1300, the stack structure 12 includes the gate layer 111, the gate dielectric layer 121, the semiconductor layer 131 and a capping layer 1310 stacked in sequence from the bottom to the top along the direction Z. That is, in the semiconductor device 1300, the stack structure 12 is the four-layered stack structure. In detail, as shown in FIG. 13, the semiconductor layer 131 is disposed between the gate dielectric layer 121 and the capping layer 1310. Further, as shown in FIG. 13, the capping layer 1310 is directly in contact with the semiconductor layer 131. In some embodiments, the capping layer 1310 is made of insulating oxides having a triangular lattice as surface. As such, the crystal lattice of the capping layer 1310 can be matched with the crystal lattice of the underlying semiconductor layer 131. In some embodiments, the pseudo-triangle lattice constant of the capping layer 1310 ranges from about 2.7 Å to about 3.1 Å. In some embodiments, examples of the said insulating oxides include SrTiO₃(111), MgO(111), or Me₂O₃, wherein Me is Al, Cr and/or Ga. In some embodiments, examples of the said insulating oxides include Al₂O₃, Cr₂O₃, or Ga₂O₃. In some embodiments, examples of the said insulating oxides include ternary oxides, such as Al₂ₓCr₂₋₂ₓO₃, Al₂ₓGa₂₋₂ₓO₃, for instance x is 0.5. In some embodiments, the capping layer 1310 is a crystalline insulating oxide layer. In certain embodiments, the capping layer 1310 is formed in a fully crystalline state. Since the gate layer 111, the dielectric layer 121, the semiconductor layer 131 and the capping layer 1310 each may be formed in a fully crystalline state, the stack structure 12 is regarded as a fully crystalline stack structure with four layers therein. In some embodiments, the capping layer 1310 is formed with a thickness ranging from about 5 nm to about 10 nm. In some embodiments, the material of the capping layer 1310 is the same as the material of the dielectric layer 121, although a different material is also possible.

According to the descriptions with respect to FIG. 1 to FIG. 2, those skilled in the art should understand that in the formation process of the semiconductor device 1300, the gate material layer 110, the gate dielectric material layer 120, the semiconductor material layer 130 and a capping material layer used for forming the capping layer 1310 are formed sequentially and continuously in the same growth process and within the same reaction chamber. Further, according to the descriptions with respect to FIG. 3 to FIG. 4, those skilled in the art should understand that in the formation process of the semiconductor device 1300, other than the ILD layer 140, a portion of the capping layer 1310 is also removed to form the contact openings 145. It is noted that during forming the contact openings 145, the capping layer 1310 acts as an etch stop layer for protecting the semiconductor layer 131 against the removing process for forming the contact openings 145. As such, in some embodiments, the capping layer 1310 is formed of a material having a different etch selectivity from adjacent layers (e.g., the ILD layer 140 and the semiconductor layer 131).

As shown in FIG. 13, the contact terminals 150 penetrate through the capping layer 1310 to be directly in contact with the top surface of the semiconductor layer 131. That is, portions of the contact terminals 150 are laterally surrounded by the capping layer 1310 or are embedded in the capping layer 1310. However, according to the descriptions with respect to FIG. 5, FIG. 7 and FIG. 8, those skilled in the art should understand that the contact terminal 150 may further extend into the semiconductor layer 131.

In accordance with an embodiment, a transistor includes a gate layer, a gate dielectric layer, a channel layer, and source and drain terminals. The gate dielectric layer is located on the gate layer. The channel layer is located on the gate dielectric layer, wherein the gate layer, the gate dielectric layer, and the channel layer form a crystalline stack structure, having a lattice structure in at least one crystal plane of a material of the gate layer, a lattice structure in at least one crystal plane of a material of the gate dielectric layer and a lattice structure in at least one crystal plane of a material of the channel layer being substantially the same, a lattice constant in the at least one crystal plane of each of the material of the gate layer, the material of the gate dielectric layer and the material of the channel layer ranges from about 2.7 Å to about 3.1 Å, and at least one of the material of the gate layer, the material of the gate dielectric layer and the material of the channel layer includes delafossite oxides. The source and drain terminals are disposed on the channel layer.

In accordance with an embodiment, a n integrated circuit includes a substrate, and an interconnection structure. The substrate has a first transistor embedded therein. The interconnection structure is disposed on the substrate, and includes dielectric layers and a second transistor. The second transistor is electrically connected with the first transistor, and includes a crystalline stack structure and contact terminals. The crystalline stack structure is embedded in one of the dielectric layers, and includes a crystalline metallic oxide layer, a crystalline semiconductor oxide layer and a crystalline insulating oxide layer. A material of the crystalline metallic oxide layer includes first delafossite oxides. The crystalline semiconductor oxide layer is located over the crystalline metallic oxide layer, wherein a material of the crystalline semiconductor oxide layer includes second delafossite oxides different from the first delafossite oxides. The crystalline insulating oxide layer is located between the crystalline metallic oxide layer and the crystalline semiconductor oxide layer. The contact terminals are disposed on the crystalline semiconductor oxide layer.

In accordance with an embodiment, a method of manufacturing a transistor includes: sequentially forming a gate material layer, a gate dielectric material layer, and a semiconductor material layer continuously in a same growth process; patterning the gate material layer, the gate dielectric material layer, and the semiconductor material layer into a stack structure including a gate layer, a gate dielectric layer and a semiconductor layer; forming a dielectric layer over the stack structure; and forming source and drain terminals on the semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor, comprising:
a gate layer;
a gate dielectric layer located on the gate layer;
a channel layer located on the gate dielectric layer, wherein the gate layer, the gate dielectric layer, and the channel layer form a crystalline stack structure, having a lattice structure in at least one crystal plane of a material of the gate layer, a lattice structure in at least one crystal plane of a material of the gate dielectric layer and a lattice structure in at least one crystal plane of a material of the channel layer being substantially the same, a lattice constant in the at least one crystal plane of each of the material of the gate layer, the material of the gate dielectric layer and the material of the channel layer ranges from about 2.7 Å to about 3.1 Å, and at least one of the material of the gate layer, the material of the gate dielectric layer and the material of the channel layer includes delafossite oxides; and
source and drain terminals disposed on the channel layer.

2. The transistor of claim 1, wherein the material of the gate layer includes metallic delafossite oxides, the material of the gate dielectric layer includes insulating oxides having a triangular plane, and the material of the channel layer includes semiconducting delafossite oxides.

3. The transistor of claim 2, wherein the material of the gate layer includes PtCoO₂, PdCoO₂, PdCrO₂, PdRhO₂, PdAlO₂.

4. The transistor of claim 2, wherein the material of the gate dielectric layer includes SrTiO₃, MgO, or Me₂O₃, wherein Me is Al, Cr and/or Ga.

5. The transistor of claim 2, wherein the material of the channel layer includes CuAlO₂, CuCrO₂, CuGaO₂, CuFeO₂, CuBO₂, AgAlO₂, AgCrO₂, AgGaO₂, AgFeO₂.

6. The transistor of claim 2, wherein the at least one crystal plane of the material of the gate layer is an ab-plane, the at least one crystal plane of the material of the gate dielectric layer is the triangular plane, and the at least one crystal plane of the material of the channel layer is an ab-plane.

7. The transistor of claim 1, wherein the source and drain terminals extend into the channel layer.

8. The transistor of claim 7, wherein the source and drain terminals are in contact with the gate dielectric layer.

9. The transistor of claim 1, wherein a material of the source and drain terminals includes metallic delafossite oxides.

10. The transistor of claim 1, wherein each of the source and drain terminals includes a first portion and a second portion on the first portion, and materials of the first portion and the second portion are different.

11. The transistor of claim 1, further comprising a capping layer located on the channel layer, wherein a material of the capping layer includes insulating oxides having a triangular plane.

12. An integrated circuit, comprising:
a substrate having a first transistor embedded therein; and
an interconnection structure disposed on the substrate, comprising;
dielectric layers; and
a second transistor electrically connected with the first transistor, comprising:
a crystalline stack structure embedded in one of the dielectric layers, comprising:
a crystalline metallic oxide layer, wherein a material of the crystalline metallic oxide layer includes first delafossite oxides;
a crystalline semiconductor oxide layer located over the crystalline metallic oxide layer, wherein a material of the crystalline semiconductor oxide layer includes second delafossite oxides different from the first delafossite oxides; and
a crystalline insulating oxide layer located between the crystalline metallic oxide layer and the crystalline semiconductor oxide layer; and;
contact terminals disposed on the crystalline semiconductor oxide layer.

13. The semiconductor device of claim 12, wherein the first delafossite oxides includes PtCoO₂, PdCoO₂, PdCrO₂, PdRhO₂, PdAlO₂; and the second delafossite oxides includes CuAlO₂, CuCrO₂, CuGaO₂, CuFeO₂, CuBO₂, AgAlO₂, AgCrO₂, AgGaO₂, AgFeO₂.

14. The semiconductor device of claim 12, wherein a material of the substrate comprising magnesium oxide or sapphire.

15. The semiconductor device of claim 12, wherein a material of the crystalline insulating oxide layer has a triangular plane, and a lattice structure in at least one crystal plane of a material of the gate layer, a lattice structure in at least one crystal plane of a material of the gate dielectric layer and a lattice structure in at least one crystal plane of a material of the channel layer are substantially the same as each other.

16. The semiconductor device of claim 12, wherein portions of the contact terminals are embedded in the crystalline semiconductor oxide layer.

17. A method of manufacturing a transistor, comprising:
sequentially forming a gate material layer, a gate dielectric material layer, and a semiconductor material layer continuously in a same growth process;
patterning the gate material layer, the gate dielectric material layer, and the semiconductor material layer into a stack structure including a gate layer, a gate dielectric layer and a semiconductor layer;
forming a dielectric layer over the stack structure; and
forming source and drain terminals on the semiconductor layer.

18. The method of claim 17, further comprising forming contact openings in the dielectric layer exposing the semiconductor layer before forming the source and drain terminals.

19. The method of claim 17, wherein during the same growth process, a capping material layer is further formed on the semiconductor material layer.

20. The method of claim 17, wherein
during the same growth process, a material layer for forming the source and drain terminals is further formed on the semiconductor material layer,
the step of forming source and drain terminals comprises patterning the material layer for forming the source and drain terminals, and
the dielectric layer is formed over the stack structure after the source and drain terminals are formed.
